(19) United States
(12) Patent Application Publication
(10) Pub. No.: US 2022/0026802 A1
(43) Pub. Date: Jan. 27, 2022

(54) PHOTOSENSITIVE RESIN COMPOSITION, METHOD FOR PRODUCING RESIST PATTERN FILM, AND METHOD FOR PRODUCING PLATED FORMED PRODUCT

(71) Applicant: JSR CORPORATION, Tokyo (JP)

(72) Inventors: Yuka SANO, Tokyo (JP); Tomoyuki MATSUMOTO, Tokyo (JP); Hirokazu SAKAKIBARA, Tokyo (JP)

(73) Assignee: JSR CORPORATION, Tokyo (JP)

(21) Appl. No.: 17/493,888

(22) Filed: Oct. 5, 2021

Related U.S. Application Data
(63) Continuation of application No. PCT/JP2020/016292, filed on Apr. 13, 2020.

(30) Foreign Application Priority Data
Apr. 24, 2019 (JP) 2019-082757

(51) Int. Cl. G03F 7/004; G03F 7/039

(52) U.S. Cl. CPC G03F 7/0045; G03F 7/039; G03F 7/0048

(57) ABSTRACT

An object of the present invention is to provide a photosensitive resin composition for suppressing standing wave traces and forming a resist pattern film having a rectangular cross section. The photosensitive resin composition of the present invention contains polymer (A) having an acid dissociative group; photoacid generator (B); carbamic acid ester (C) having a hydroxyl group; and solvent (D), the solvent (D) containing at least one solvent (D1) selected from, for example, propylene glycol monomethyl ether acetate and at least one solvent (D2) selected from, for example, dipropylene glycol dimethyl ether.

### CROSS-REFERENCE TO RELATED APPLICATIONS

The present application is a continuation application of International Application No. PCT/JP2020/016292, filed Apr. 13, 2020, which claims priority to Japanese Patent Application No. 2019-082757 filed Apr. 24, 2019. The contents of these applications are incorporated herein by reference in their entirety.

### TECHNICAL FIELD

The present invention relates to a photosensitive resin composition, a method for producing a resist pattern film, and a method for producing a plated formed product.

### BACKGROUND ART

To improve the performance of mobile devices such as smartphones and tablet terminals, semiconductor chips with different functions are packaged by using high-density packaging technology such as FO-WLP (Fan-Out Wafer Level Package), FO-PLP (Fan-Out Panel Level Package), TSV (Through Silicon Via), and silicon interposers.

In such packaging technology, the wiring and bump electrodes (bumps) used for electrical connections between semiconductor chips also become denser. Therefore, the resist pattern film used for forming wiring and bumps is also required to be fine and dense.

Wiring and bumps are typically plated formed products, and are produced by applying a photosensitive resin composition onto the metal film of a substrate having a metal film such as a copper film to form a resist coating, exposing and developing the resist coating with a mask to form a thick resist pattern film, and plating the surface of the substrate with the thick resist pattern film as a mold (refer to Patent Literatures 1 and 2).

### CITATION LIST

### Patent Literature

Patent Literature 1: JP 2010-008972 A

Patent Literature 2: JP 2006-330368 A

### SUMMARY OF INVENTION

### Technical Problem

When the pattern size and the pattern interval in the resist pattern film become fine and dense, there cannot be ignored roughness (standing wave trace) of the resist pattern film due to standing waves caused by incident light and reflected light from a metal film such as a copper substrate in exposure.

In addition, when the wiring and the bumps become fine and dense, the distance between the adjacent wirings or bumps becomes short, the contact area between the wiring or the bumps and the metal film such as a copper film becomes small, and therefore the resist pattern is required to have a rectangular cross section in order to produce a plated formed product having a rectangular cross section.

The objects of the present invention are to provide: a photosensitive resin composition for forming a resist pattern film having a rectangular cross section; a method for producing a resist pattern film with the photosensitive resin composition; and a method for producing a plated formed product with the resist pattern film.

### Solution to Problem

The present inventors have intensively investigated to solve the above problems. As a result, it has been found that the above problems can be solved by the following aspects, and the present invention has been completed. That is, the present invention relates to, for example, the following [1] to [7].

[1] A photosensitive resin composition containing:

polymer (A) having an acid dissociative group; photoacid generator (B); carbamic acid ester (C) having a hydroxyl group; and solvent (D),

the solvent (D) containing:

at least one solvent (D1) selected from propylene glycol monomethyl ether acetate, propylene glycol monomethyl ether, ethyl lactate, methyl 3-methoxypropionate, and cyclohexanone; and

at least one solvent (D2) selected from dipropylene glycol dimethyl ether, dipropylene glycol methyl ethyl ether, dipropylene glycol diethyl ether, dipropylene glycol methyl ether acetate, dipropylene glycol ethyl ether acetate, 3-methoxybutyl acetate, 1,4-butanediol diacetate, and 1,3-butylene glycol diacetate.

[2] The photosensitive resin composition according to [1], wherein a content ratio of the solvent (D1) in 100% by mass of the solvent (D) is 70 to 99% by mass, and a content ratio of the solvent (D2) is 1 to 30% by mass.

[3] The photosensitive resin composition according to [1] or [2], wherein the solvent (D1) is propylene glycol monomethyl ether acetate.

[4] The photosensitive resin composition according to [1] to [3], wherein the carbamic acid ester (C) having a hydroxyl group is a carbamic acid ester having an acid dissociative group.

[5] The photosensitive resin composition according to [1] to [4], wherein a content of the carbamic acid ester (C) having a hydroxyl group in the photosensitive resin composition is 0.1 to 1 parts by mass with respect to 100 parts by mass of the solvent (D2).

[6] A method for producing a resist pattern film, the method including:

a step (1) of forming a resin film of the photosensitive resin composition according to any one of [1] to [5] on the metal film of a substrate having the metal film;

a step (2) of exposing at least a part of the resin film; and

a step (3) of developing the exposed resin film.

[7] A method for producing a plated formed product, the method including a step of performing a plating treatment with a substrate, as a mold, having a resist pattern film formed by the method for producing the resist pattern film according to [6].

### Advantageous Effects of Invention

The photosensitive resin composition of the present invention can suppress standing wave trace and form a resist pattern film having a rectangular cross section.

### BRIEF DESCRIPTION OF DRAWINGS

FIG. 1 is a schematic view for describing measurement of a shape of a resist pattern film of an example.

FIG. 2 is an enlarged portion of a portion of a resist pattern cross section in contact with a substrate according to an embodiment, and is a schematic view for describing measurement of a width of a standing wave trace.

### DESCRIPTION OF EMBODIMENTS

Unless otherwise specified, each component exemplified in the present description, for example, each component in the photosensitive resin composition and each structural unit in polymer (A), may be included singly, or two or more thereof may be included.

[Photosensitive Resin Composition]

The photosensitive resin composition of the present invention (hereinafter also referred to as “the present composition”) contains polymer (A) having an acid dissociative group (hereinafter, also referred to as “polymer (A)”); photoacid generator (B); carbamic acid ester (C) having a hydroxyl group (hereinafter, also referred to as “compound (C)”); and solvent (D), wherein solvent (D) contains: at least one solvent (D1) selected from propylene glycol monomethyl ether acetate, propylene glycol monomethyl ether, ethyl lactate, methyl 3-methoxypropionate, and cyclohexanone; and at least one solvent (D2) selected from dipropylene glycol dimethyl ether, dipropylene glycol methyl ethyl ether, dipropylene glycol diethyl ether, dipropylene glycol methyl ether acetate, dipropylene glycol ethyl ether acetate, 3-methoxybutyl acetate, 1,4-butanediol diacetate, and 1,3-butylene glycol diacetate.

<Polymer (A)>

Polymer (A) has an acid dissociative group.

The acid dissociative group is a group that can be dissociated by the action of an acid generated from photoacid generator (B). As a result of the dissociation, acidic functional groups such as a carboxy group and a phenolic hydroxyl group are generated in polymer (A). As a result, the solubility of polymer (A) in an alkaline developer changes, and the composition can form a resist pattern film.

Polymer (A) has an acidic functional group protected by an acid dissociative group. Examples of the acidic functional group include a carboxy group and a phenolic hydroxyl group. Examples of polymer (A) include a (meth)acrylic resin in which a carboxy group is protected by an acid dissociative group, and a polyhydroxystyrene resin in which a phenolic hydroxyl group is protected by an acid dissociative group.

The polystyrene-equivalent weight average molecular weight (Mw) of polymer (A) measured by gel permeation chromatography is typically 1000 to 500000, preferably 3000 to 300000, more preferably 10000 to 100000, and still more preferably 20000 to 60000.

The ratio of Mw of polymer (A) to the polystyrene-equivalent number average molecular weight (Mn) measured by gel permeation chromatography, (Mw/Mn), is typically 1 to 5, and preferably 1 to 3.

The present composition can contain one or more polymers (A). The content ratio of polymer (A) in the present composition is typically 70 to 99.5% by mass, preferably 80 to 99% by mass, and more preferably 90 to 98% by mass with respect to the solid content of 100% by mass of the composition. The solid content refers to all components other than mixed solvent (D).

The content ratio of polymer (A) in the present composition is typically 5 to 60% by mass, and preferably 10 to 50% by mass. Within the above range, there can be obtained a resist pattern film having a rectangular cross section at a film thickness suitable for the production of a plated shaped product.

<<Structural Unit (a1)>>

Polymer (A) typically has structural unit (a1) having an acid dissociative group.

Examples of structural unit (a1) include the structural unit represented by formula (a1-10) and the structural unit represented by formula (a1-20), and the structural unit represented by formula (a1-10) is preferable.

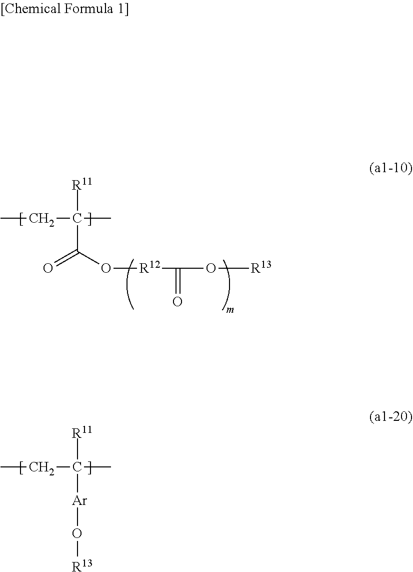

The meanings of the symbols in formulas (a1-10) and (a1-20) are as follows.

R¹¹ is a hydrogen atom, an alkyl group having 1 to 10 carbon atoms, or a group obtained by substituting at least one hydrogen atom in the alkyl group (hereinafter also referred to as “substituted alkyl group”) with another group such as a halogen atom including a fluorine atom and a bromine atom, an aryl group including a phenyl group, a hydroxyl group, and an alkoxy group.

R¹² is a divalent organic group having 1 to 10 carbon atoms. Ar is an arylene group having 6 to 10 carbon atoms. R¹³ is an acid dissociative group.

m is an integer of 0 to 10, preferably an integer of 0 to 5, and more preferably an integer of 0 to 3. Examples of the alkyl group having 1 to 10 carbon atoms include a methyl group, an ethyl group, an n-propyl group, an isopropyl group, an n-butyl group, a pentyl group, and a decyl group.

Examples of the divalent organic group having 1 to 10 carbon atoms include: an alkanediyl group having 1 to 10 carbon atoms such as a methylene group, an ethylene group, a propane-1,3-diyl group, a propane-1,2-diyl group, and a decane-1,10-diyl group; and a group obtained by substituting at least one hydrogen atom in the alkanediyl group with another group such as a halogen atom including a fluorine atom and a bromine atom, an aryl group including a phenyl group, a hydroxyl group, and an alkoxy group.

Examples of the arylene group having 6 to 10 carbon atoms include a phenylene group, a methylphenylene group, and a naphthylene group.

Examples of the acid dissociative group include a group that dissociates due to the action of an acid and thereby generates an acidic functional group such as a carboxy group and a phenolic hydroxyl group in polymer (A). Specific examples thereof include an acid dissociative group represented by formula (g1) and a benzyl group, and the acid dissociative group represented by formula (g1) is preferable.

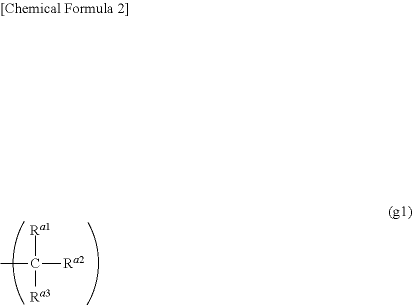

In the formula (g1), R^{a1} to R^{a3} each independently represent an alkyl group, an alicyclic hydrocarbon group, or a group obtained by substituting at least one hydrogen atom in the alkyl group or the alicyclic hydrocarbon group with another group such as a halogen atom including a fluorine atom and a bromine atom, an aryl group including a phenyl group, a hydroxyl group, and an alkoxy group. R^{a1} and R^{a2} may be bonded to each other to form an alicyclic structure together with the carbon atom C to which R^{a1} and R^{a2} are bonded.

Examples of the alkyl group of R^{a1} to R^{a3} include an alkyl group having 1 to 10 carbon atoms such as a methyl group, an ethyl group, an n-propyl group, an isopropyl group, an n-butyl group, a pentyl group, and a decyl group.

Examples of the alicyclic hydrocarbon group of R^{a1} to R^{a3} include: a monocyclic saturated cyclic hydrocarbon groups such as a cyclobutyl group, a cyclopentyl group, a cyclohexyl group, a cycloheptyl group, and a cyclooctyl group; a monocyclic unsaturated cyclic hydrocarbon group such as a cyclobutenyl group, a cyclopentenyl group, and a cyclohexenyl group; and a polycyclic saturated cyclic hydrocarbon group such as a norbornyl group, an adamantyl group, a tricyclodecyl group, and a tetracyclododecyl group.

Examples of the alicyclic structure formed by R^{a1}, R^{a2}, and carbon atom C includes: a monocyclic saturated cyclic hydrocarbon structure such as cyclobutyl, cyclopentyl, cyclohexyl, cycloheptyl, and cyclooctyl; a monocyclic unsaturated cyclic hydrocarbon structure such as cyclobutenyl, cyclopentenyl, and cyclohexenyl; and a polycyclic saturated cyclic hydrocarbon structure such as norbornyl, adamantyl, tricyclodecyl, and tetracyclododecyl.

The groups represented by formulas (g11) to (g15) are preferable as the acid dissociative group represented by formula (g1).

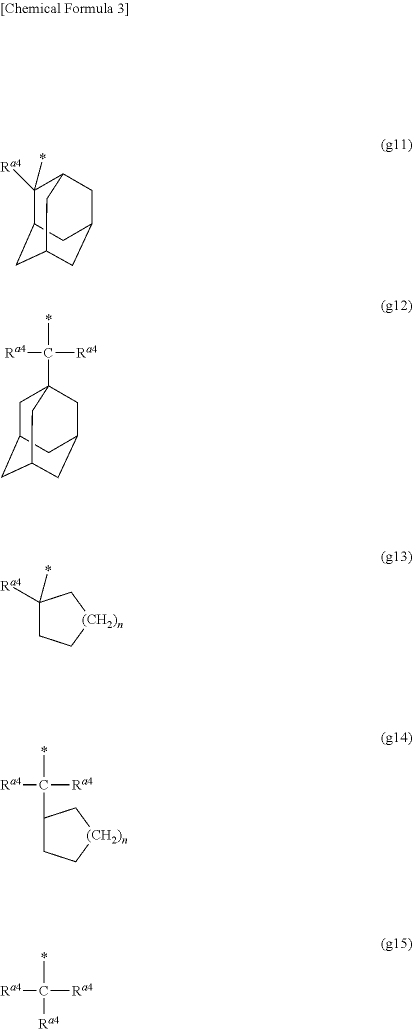

In formulas (g11) to (g15), Rao each independently represents an alkyl group having 1 to 10 carbon atoms such as a methyl group, an ethyl group, an isopropyl group, and an n-butyl group, and n is an integer of 1 to 4. Each ring structure in formulas (g11) to (g14) may have one or more substituents such as an alkyl group having 1 to 10 carbon atoms, a halogen atom including a fluorine atom and a bromine atom, a hydroxyl group, and an alkoxy group. * indicates a bonding hand.

In addition to the structural units shown in formulas (a1-10) and (a1-20), examples of structural unit (a1) include: structural units having an acetal-based acid dissociative group described in JP 2005-208366 A, JP 2000-194127 A, U.S. Patent No. 2002/0110750, and U.S. Patent No. 2006/0210913; a structural unit having a sultone ring described in U.S. Patent No. 2013/0095425; and structural units having a crosslinked acid dissociative group described in such as JP 2000-214587 A and U.S. Pat. No. 6,156,481.

The structural units described in the above publication shall be described in the present description.

Polymer (A) can have one or more structural units (a1).

The content ratio of structural unit (a1) in polymer (A) is typically 10 to 50 mol %, preferably 15 to 45 mol %, and more preferably 20 to 40 mol %.

In the present description, the content ratio of each structural unit in polymer (A) is a value when the total of all the structural units constituting polymer (A) is 100 mol %. Each of the structural units is typically derived from a monomer in the synthesis of polymer (A). The content ratio of each structural unit can be measured by ¹H-NMR.

In one embodiment, polymer (A) preferably has the structural unit shown in formula (a1-10) in which R¹¹ is a hydrogen atom, and the structural unit represented by formula (a1-10) in which R¹¹ is an alkyl group having 1 to 10 carbon atoms or a substituted alkyl group, as structural unit (a1). Such an embodiment tends to allow further improvement of the resolution of the present composition, and to allow further improvement of the swelling resistance and crack resistance to a plating solution for the resist pattern film.

<<Structural Unit (a2)>>

Polymer (A) can further have structural unit (a2) having a group that promotes solubility in an alkaline developer (hereinafter, also referred to as “solubility promoting group”). Polymer (A) having structural unit (a2) can adjust lithographic characteristics such as the resolution, sensitivity, and depth of focus of the resin pattern formed from the present composition.

Examples of structural unit (a2) includes a structural unit having at least one group or structure selected from a carboxy group, a phenolic hydroxyl group, an alcoholic hydroxyl group, a lactone structure, a cyclic carbonate structure, a sultone structure, and a fluoroalcohol structure (those corresponding to structural unit (a1) are excluded). Of these, a structural unit having a phenolic hydroxyl group is preferable because of being capable of forming a resist pattern film that is resistant to pressing from plating when forming a plated formed product.

Examples of the structural unit having a carboxy group include a structural unit derived from the monomer such as (meth)acrylic acid, crotonic acid, maleic acid, fumaric acid, cinnamic acid, 2-carboxyethyl(meth)acrylate, 2-carboxypropyl(meth)acrylate, and 3-carboxypropyl(meth)acrylate, and a structural unit described in JP 2002-341539 A.

Examples of the structural unit having a phenolic hydroxyl group include a structural unit derived from the monomer having a hydroxyaryl group such as 2-hydroxystyrene, 4-hydroxystyrene, 4-isopropenylphenol, 4-hydroxy-1-vinylnaphthalene, 4-hydroxy-2-vinylnaphthalene, and 4-hydroxyphenyl(meth)acrylate. Examples of the hydroxyaryl group include: a hydroxyphenyl group such as a hydroxyphenyl group, a methylhydroxyphenyl group, a dimethylhydroxyphenyl group, a dichlorohydroxyphenyl group, a trihydroxyphenyl group, and a tetrahydroxyphenyl group; and a hydroxynaphthyl group such as a hydroxynaphthyl group and a dihydroxynaphthyl group.

Examples of the structural unit having an alcoholic hydroxyl group include a structural unit derived from the monomer such as 2-hydroxyethyl(meth)acrylate and 3-(meth)acryloyloxy-4-hydroxytetrahydrofuran, and a structural unit described in JP 2009-276607 A.

Examples of the structural unit having a lactone structure include the structural units described in JP 2017-058421 A, U.S. Patent No. 2010/0316954, JP 2010-138330 A, U.S. Patent No. 2005/0287473, JP 2016-098350 A, and U.S. Patent No. 2015/0323865.

Examples of the structural unit having a cyclic carbonate structure include a structural unit described in JP 2017-058421 A, JP 2009-223294 A, and JP 2017-044875 A.

Examples of the structural unit having a sultone structure include the structural units described in JP 2017-058421 A, JP 2014-029518 A, U.S. Patent No. 2016/0085149, and JP 2013-007846 A.

Examples of the structural unit having a fluoroalcohol structure include a structural unit described in JP 2004-083900 A, JP 2003-002925 A, JP 2004-145048 A, and JP 2005-133066 A.

The structural units described in the above publication shall be described in the present description.

Polymer (A) can have one or more structural units (a2).

The content ratio of structural unit (a2) in polymer (A) is typically 10 to 80 mol %, preferably 20 to 65 mol %, and more preferably 25 to 60 mol %. As long as the content ratio of structural unit (a2) is within the above range, the dissolution rate in an alkaline developer can be increased, and as a result, the resolution of the present composition in a thick film can be improved.

Polymer (A) can have structural unit (a2) in the same polymer as or different polymer from the polymer having structural unit (a1); however, polymer (A) preferably has the structural units (a1) to (a2) in the same polymer.

<<Structural Unit (a3)>>

Polymer (A) can further have another structural unit (a3) other than structural units (a1) to (a2).

Examples of structural unit (a3) include:

a structural unit derived from a vinyl compound such as styrene, 2-methylstyrene, 3-methylstyrene, 4-methylstyrene, 2-methoxystyrene, 3-methoxystyrene, 4-methoxystyrene;

a structural unit derived from an aliphatic (meth)acrylic acid ester compound such as methyl(meth)acrylate, ethyl(meth)acrylate, n-butyl(meth)acrylate, n-pentyl(meth)acrylate, n-hexyl(meth)acrylate, 2-ethylhexyl(meth)acrylate, 2-methoxyethyl(meth)acrylate, 2-methoxybutyl(meth)acrylate, lauroyloxytetraethyleneglycol(meth)acrylate, lauroyloxydipropyleneglycol(meth)acrylate, and lauroyloxytripropyleneglycol(meth)acrylate;

a structural unit derived from an alicyclic (meth)acrylic acid ester compound such as cyclopentyl(meth)acrylate, norbornyl(meth)acrylate, isobornyl(meth)acrylate, tricyclodecanyl(meth)acrylate, dicyclopentenyl(meth)acrylate, tetrahydrofuranyl(meth)acrylate, and tetrahydropyranyl(meth)acrylate;

a structural unit derived from an aromatic ring-containing (meth)acrylic acid ester compound such as phenyl(meth)acrylate and phenethyl(meth)acrylate;

a structural unit derived from an unsaturated nitrile compound such as (meth)acrylonitrile, croton nitrile, maleine nitrile, and fumaronitrile;

a structural unit derived from an unsaturated amide compound such as (meth)acrylamide and N,N-dimethyl(meth)acrylamide; and

a structural unit derived from an unsaturated imide compound such as maleimide, N-phenylmaleimide, and N-cyclohexylmaleimide.

Polymer (A) can have one or more structural units (a3).

The content ratio of structural unit (a3) in polymer (A) is typically 40 mol % or less.

Polymer (A) can have structural unit (a3) in the same polymer as or different polymer from the polymer having structural unit (a1) and/or structural unit (a2); however, polymer (A) preferably has the structural units (a1) to (a3) in the same polymer.

### <<Method for Producing Polymer (A)>>

Polymer (A) can be produced by polymerizing the monomer corresponding to each structural unit in a suitable polymerization solvent by a known polymerization method such as an ionic polymerization method or a radical polymerization method. Of these, the radical polymerization method is preferable.

Examples of the radical polymerization initiator used in the radical polymerization method include: the azo compound such as 2,2′-azobisisobutyronitrile, 2,2′-azobis(methylisobutyrate), and 2,2′-azobis-(2,4-dimethylvaleronitrile); and an organic peroxide such as benzoylperoxide, laurylperoxide, and t-butylperoxide.

In the polymerization, a molecular weight modifier such as a mercaptan compound and a halogen hydrocarbon can be used, as necessary.

### <Photoacid Generator (B)>

Photoacid generator (B) is a compound that generates an acid by exposure. The action of this acid dissociates the acid dissociative group in polymer (A) to generate an acidic functional group such as a carboxy group and a phenolic hydroxyl group. As a result, the exposed portion of the resin film formed from the present composition becomes easily soluble in an alkaline developer, and a positive resist pattern film can be formed. As described above, the present composition functions as a chemically amplified positive photosensitive resin composition.

Examples of photoacid generator (B) include compounds described in JP 2004-317907 A, JP 2014-157252 A, JP 2002-268223 A, JP 2017-102260 A, JP 2016-018075 A, and JP 2016-210761 A. These shall be described herein.

Specific examples of photoacid generator (B) include: an onium salt compound such as diphenyliodonium trifluoromethanesulfonate, diphenyliodonium p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenylsulfonium hexafluoroantimonate, triphenylsulfonium hexafluorophosphate, 4-t-butylphenyl diphenylsulfonium trifluoromethanesulfonate, 4-t-butylphenyl diphenylsulfonium benzenesulfonate, 4,7-di-n-butoxynaphthyltetrahydrothiophenium trifluoromethanesulfonate, 4,7-di-n-butoxynaphthyltetrahydrothiophenium bis(trifluoromethanesulfonyl)imide anion, 4,7-di-n-butoxynaphthyltetrahydrothiophenium bis(nonafluorobutylsulfonyl)imide anion, and 4,7-di-n-butoxynaphthyltetrahydrothiophenium tris(nonafluorobutylsulfonyl)methide; a halogen-containing compound such as 1,10-dibromo-n-decane, 1,1-bis(4-chlorophenyl)-2,2,2-trichloroethane, phenyl-bis(trichloromethyl)-s-triazine, 4-methoxyphenyl-bis(trichloromethyl)-s-triazine, styryl-bis(trichloromethyl)-s-triazine, and naphthyl-bis(trichloromethyl)-s-triazine; a sulfone compound such as 4-trisphenacyl sulfone, mesitylphenacyl sulfone, and bis(phenylsulfonyl)methane; a sulfonic acid compound such as benzointosilate, pyrogalloltristrifluoromethanesulfonate, o-nitrobenzyltrifluoromethanesulfonate, and o-nitrobenzyl-p-toluenesulfonate; a sulfone imide compound such as N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)-4-butyl-naphthylimide, N-(trifluoromethylsulfonyloxy)-4-propylthio-naphthylimide, N-(4-methylphenylsulfonyloxy)succinimide, N-(4-methylphenylsulfonyloxy)phthalimide, N-(4-methylphenylsulfonyloxy)diphenylmaleimide, N-(4-methylphenylsulfonyloxy)bicyclo[2.2.1]hept-5-ene-2,3-dicarboxyimide, N-(4-fluorophenylsulfonyloxy)bicyclo[2.1.1]heptane-5,6-oxy-2,3-dicarboxyimide, and N-(4-fluorophenylsulfonyloxy)naphthylimide, N-(10-campa-sulfonyloxy)naphthylimide; and a diazomethane compound such as bis(trifluoromethylsulfonyl)diazomethane, bis(cyclohexylsulfonyl)diazomethane, bis(phenylsulfonyl)diazomethane, bis(p-toluenesulfonyl)diazomethane, methylsulfonyl-p-toluenesulfonyldiazomethane, cyclohexylsulfonyl-1,1-dimethylethylsulfonyldiazomethane, and bis(1,1-dimethylethylsulfonyl)diazomethane.

Of these, the onium salt compound and sulfonimide compound are preferable because of being capable of forming the resist pattern film that is excellent in resolution and resistance to a plating solution. The present composition can contain one or more photoacid generators (B).

The content of photoacid generator (B) in the present composition is typically 0.1 to 20 parts by mass, preferably 0.3 to 15 parts by mass, and more preferably 0.5 to 10 parts by mass with respect to 100 parts by mass of polymer (A). The content ratio of photoacid generator (B) contained in the present composition is typically 0.1 to 6% by mass, and preferably 0.5 to 4% by mass.

### <Compound (C)>

Compound (C) is a carbamic acid ester having a hydroxyl group. Compound (C) is a component that functions as a quencher in the chemically amplified positive photosensitive resin composition. For example, compound (C) is used to control, in the resin film, the diffusion of the acid generated by exposure from photoacid generator (B), and can thus improve the resolution of the present composition.

Compound (C) has a hydroxyl group and a carbamic acid ester structure, and therefore the distribution coefficient (C log P) thereof becomes a value close to the distribution coefficient of solvent (D2). As a result, compound (C) and solvent (D2) are compatible with each other, allowing the standing wave trace to be suppressed and a resist pattern film having a rectangular cross section to be formed. The distribution coefficient of compound (C) is typically 0.1 to 1.5, preferably 0.3 to 1.4, and more preferably 0.6 to 1.1.

Examples of compound (C) include acid-non-dissociative carbamic acid esters such as 1-(methylcarbonyl)-2-piperidinemethanol, 1-(ethylcarbonyl)-2-piperidinemethanol, 1-(methylcarbonyl)-4-hydroxypiperidine, 1-(ethylcarbonyl)-4-hydroxypiperidine, and N-(methylcarbonyl)-D-glucosamine; and carbamic acid esters having an acid dissociative group (hereinafter also referred to as “acid-dissociative carbamic acid ester”) such as 1-(tert-butoxycarbonyl)-2-piperidinemethanol, 1-(tert-butoxycarbonyl)-4-hydroxypiperidine, N-(tert-butoxycarbonyl)-L-alanine, 2-(tert-butoxycarbonylamino)-3-cyclohexyl-1-propanol, 2-(tert-butoxycarbonylamino)-3-methyl-1-butanol, 2-(tert-butoxycarbonylamino)-3-phenylpropanol, (tert-butoxycarbonylamino)-3-phenyl-1-propanol, 2-(tert-butoxycarbonylamino)-1-propanol, N-(tert-butoxycarbonyl)ethanolamine, N-(tert-butoxycarbonyl)-D-glucosamine, 1-(tert-butoxycarbonyl)-2-pyrrolidinemethanol, N-(tert-butoxycarbonyl)-L-valinol, tert-butyl N-(3-hydroxypropyl)carbamate, and tert-butyl-N-(2,3-dihydroxypropyl)carbamate.

Of these, acid-dissociative carbamic acid esters are preferable. The acid-dissociative carbamic acid ester undergoes decomposition of the acid dissociative group by the acid generated from photoacid generator (B) by exposure, and thus the basicity of compound (C) can be greatly changed before and after exposure, thereby allowing the resolution of the photosensitive resin composition to be improved.

The present composition can contain one or more compounds (C). The lower limit of the content of compound (C) in the present composition is typically 0.001 parts by mass or more, and preferably 0.01 parts by mass or more, with respect to 100 parts by mass of polymer (A), and the upper limit is typically 10 parts by mass or less, and preferably 5 parts by mass or less. In addition, the lower limit of the content of compound (C) in the present composition with respect to solvent (D2) is typically 0.1 parts by mass or more, and preferably 0.2 parts by mass or more, with respect to 100 parts by mass of solvent (D2), and the upper limit is typically 1 part by mass or less, preferably 0.8 parts by mass or less, and more preferably 0.5 parts by mass or less.

### <Solvent (D)>

Solvent (D) contains: at least one solvent (D1) selected from propylene glycol monomethyl ether acetate, propylene glycol monomethyl ether, ethyl lactate, methyl 3-methoxypropionate, and cyclohexanone; and at least one solvent (D2) selected from dipropylene glycol dimethyl ether, dipropylene glycol methyl ethyl ether, dipropylene glycol diethyl ether, dipropylene glycol methyl ether acetate, dipropylene glycol ethyl ether acetate, 3-methoxybutyl acetate, 1,4-butanediol diacetate, and 1,3-butylene glycol diacetate.

The lower limit of the content ratio of solvent (D1) in 100% by mass of solvent (D) is preferably 70% by mass or more, more preferably 80% by mass or more, and still more preferably 85% by mass or more, and the upper limit is preferably 99% by mass or less, more preferably 95% by mass or less, and still more preferably 92% by mass or less.

The lower limit of the content ratio of solvent (D2) in 100% by mass of solvent (D) is preferably 1% by mass or more, more preferably 5% by mass or more, and still more preferably 8% by mass or more, and the upper limit is preferably 30% by mass or less, more preferably 20% by mass or less, and still more preferably 15% by mass or less. When the content ratio of solvent (D1) and solvent (D2) in solvent (D) satisfies the above range, the standing wave trace is suppressed, allowing a resist pattern film having a rectangular cross section to be formed.

In order to reduce the standing wave trace of the resist pattern film, the present composition diffuses the acid generated by the exposure in the resin film. The acid easily diffuses in the resin film including the solvent, and therefore it is estimated that the standing wave trace of the resist pattern film can be efficiently reduced by the diffusion of the acid.

Solvent (D1) has a boiling point (standard boiling point) of 120 to 160° C. under 1 atm, and most of the solvent is volatilized and hardly remains in the resin film after the photosensitive resin composition is applied onto the substrate. Whereas, solvent (D2) is a solvent having a standard boiling point of more than 170° C., and therefore most of the solvent remains in the resin film without being volatilized after the photosensitive resin composition is applied onto the substrate. As described above, it is estimated that the present composition containing solvent (D2) in the resin film easily diffuses the acid generated by exposure into the resin film, thereby allowing the standing wave trace of the resist pattern film to be efficiently reduced.

Whereas, when a solvent is included in a resin film and a low molecular weight component and the solvent are hardly miscible with each other, there is a possibility that the low molecular weight component is unevenly distributed in the resin film. A quencher that is a low molecular weight component affects the diffusion of acid, and therefore it is estimated that a resist pattern film having a rectangular cross section fails to be formed when the quencher is unevenly distributed in the resin film.

Generally, the compatibility between substances is improved when the distribution coefficients thereof are close to each other, and therefore it is estimated that in the present composition, the uneven distribution of the quencher in the resin film is eliminated by making the distribution coefficient of the solvent (in the present composition, solvent (D2)) remaining in the resin film and the distribution coefficient of the quencher close to each other, allowing a resist pattern film having a rectangular cross section to be formed. The distribution coefficient of solvent (D2) is 0.3 to 1.2, which is close to the distribution coefficient of compound (C) that is quencher. As described above, it is estimated that uneven distribution of compound (C) in the resin film is eliminated by containing solvent (D2) and compound (C) in the present composition, allowing a resist pattern film having a rectangular cross section to be formed.

The distribution coefficient can be calculated by measuring a concentration ratio (distribution coefficient) of the compound in each liquid layer when the compound is dissolved in a mixed solution of water and 1-octanol. The higher compound concentration in 1-octanol with compared to water indicates the numerical value showing higher hydrophobicity (lipid solubility). The distribution coefficient can also be determined by Chem Draw Professional 17.1.

Solvent (D) can contain a solvent (hereinafter, “solvent (D3)”) other than solvent (D1) and solvent (D2). Examples of solvent (D3) include: alcohol solvents such as ethylene glycol monomethyl ether, ethylene glycol monoethyl ether, diethylene glycol, and diethylene glycol monoethyl ether; ester solvents such as ethyl acetate, ethyl 2-hydroxy-2-methylpropionate, methyl acetoacetate, ethyl ethoxyacetate, and γ-butyrolactone; ketone solvents such as methyl amyl ketone; alkylene glycol dialkyl ethers such as diethylene glycol dimethyl ether, diethylene glycol diethyl ether, and diethylene glycol di-n-propyl ether; and alkylene glycol monoalkyl ether acetates such as ethylene glycol monomethyl ether acetate and ethylene glycol monoethyl ether acetate. Solvent (D3) may be used singly or in combination of two or more.

The content ratio of solvent (D3) in 100% by mass of solvent (D) is typically less than 30% by mass, preferably less than 20% by mass, and more preferably 0% by mass.

The solid content concentration of the present composition is typically 5% by mass or more, and preferably 10 to 50% by mass. Within the above range, the standing wave trace is suppressed at a thickness optimal for the production of a plated formed product such as a wiring or a bump, and a resist pattern film having a rectangular cross section can be formed.

<Other components>

The present composition can further contain other components. Examples of the other components include: a quencher other than compound (C); a surfactant that has the effect of improving the coatability and antifoaming properties of the photosensitive resin composition; a sensitizer that absorbs exposure light and improves the acid generation efficiency of the photoacid generator; an alkali-soluble resin or low-molecular-weight phenol compound that controls the dissolution rate of the resin film formed from the photosensitive resin composition in an alkaline developer; an ultraviolet absorber that blocks the light reaction caused by the scattered light wrapping around the unexposed area during exposure; a thermal polymerization inhibitor that enhances the storage stability of the photosensitive resin composition; an adhesion aid such as a mercapto compound, an imidazole compound, and a silane coupling agent that improves adhesion between a resist pattern film and a metal film of a substrate; and others such as an antioxidant and an inorganic filler.

### <Production of Photosensitive Resin Composition>

The present composition can be produced by uniformly mixing each of the above components. In addition, in order to remove impurities, each of the above components are uniformly mixed, and then the obtained mixture can be filtered with a filter such as a membrane filter or a capsule cartridge filter.

### [Method for Producing Resist Pattern Film]

The method for producing a resist pattern film of the present invention includes: a step (1) of forming a resin film of the photosensitive resin composition on the metal film of a substrate having metal film; a step (2) of exposing at least a part of the resin film; and a step (3) of developing the exposed resin film.

### <Step (1)>

Examples of the substrate include a semiconductor substrate and a glass substrate. The shape of the substrate is not particularly limited, and the surface shape includes a flat plate shape and an uneven shape, and the shape of the substrate includes a circular shape and a square shape. In addition, there is no limit to the size of the substrate.

Examples of the metal film include a film containing a metal such as aluminum, copper, silver, gold and palladium, and a film containing an alloy containing two or more the metals, and a copper film, that is, the film including copper and/or copper alloy is preferable. The thickness of the metal film is typically 100 to 10000 Å, and preferably 500 to 2000 Å. The metal film is typically provided on the surface of the substrate. The metal film can be formed by a method such as a sputtering method.

The resin film is formed by applying the present composition onto the metal film of a substrate having a metal film.

Examples of the coating method of the present composition include a spin coating method, a roll coating method, a screen printing method, and an applicator method, and of these, the spin coating method and the screen printing method are preferable.

The present composition is applied, and then the present composition applied can be heat-treated for the purpose of, for example, volatilizing solvent (D). The conditions for the heat treatment are typically at 50 to 200° C. for 0.5 to 20 minutes. The thickness of the resin film is typically 0.1 to 80 μm, preferably 0.5 to 50 μm, and more preferably 1 to 10 μm.

### <Step (2)>

In step (2), at least a part of the resin film formed in step (1) is exposed. The exposure is typically performed selectively on the resin film by a reduced projection exposure via a photomask having a predetermined mask pattern. Examples of the exposure light include ultraviolet rays or visible light having a wavelength of 150 to 600 nm, and preferably 200 to 500 nm. Examples of the light source of the exposure light include a low-pressure mercury lamp, a high-pressure mercury lamp, an ultra-high-pressure mercury lamp, a metal halide lamp, and a laser. The exposure amount can be appropriately selected depending on the type of exposure light, the type of the present composition, and the thickness of the resin film, and is typically 100 to 20000 mJ/cm².

After the exposure to the resin film, the resin film can be heat-treated before development. The conditions for the heat treatment are typically 70 to 180° C. for 0.5 to 10 minutes, preferably 75 to 160° C. for 0.8 to 7 minutes, and more preferably 80 to 140° C. for 1.0 to 5 minutes.

The heat treatment can diffuse the acid generated from photoacid generator (B) in the resin film, allowing the standing wave effect generated in the resin film to be reduced.

### <Step (3)>

In step (3), the resin film exposed in step (2) is developed to form a resist pattern film. Development is typically performed by using an alkaline developer. Examples of the developing method include a shower method, a spray method, a dipping method, a liquid filling method, and a paddle method. The developing conditions are typically at 10 to 30° C. for 1 to 30 minutes.

Examples of the alkaline developer include an aqueous solution containing one or more alkaline substances. Examples of the alkaline substance include sodium hydroxide, potassium hydroxide, sodium carbonate, sodium silicate, aqueous ammonia, ethylamine, n-propylamine, diethylamine, triethylamine, monoethanolamine, diethanolamine, triethanolamine, tetramethylammonium hydroxide, tetraethylammonium hydroxide, choline, pyrrole, and piperidine. The concentration of the alkaline substance in the alkaline developer is typically 0.1 to 10% by mass. The alkaline developer can further contain, for example, an organic solvent such as methanol, or ethanol and/or a surfactant.

The resist pattern film formed by development can be washed with water for example. Then, the above resist pattern film can be dried by using an air gun or a hot plate.

As described above, the resist pattern film that serves as a mold for forming a plated formed product can be formed on the metal film of the substrate, and thus a plating substrate having the resist pattern film on the metal film can be obtained. The thickness of the resist pattern film is typically 0.1 to 80 μm, preferably 0.5 to 50 μm, and more preferably 1.0 to 10 μm.

A shape suitable for the type of the plated formed product can be selected as the shape of the opening of the resist pattern film. When the plated formed product is a wiring, the shape is linear as viewed from the top of the opening of a resist pattern film, and when the plated formed product is a bump, the shape is square as viewed from the top of the opening of the resist pattern film.

When the shape of the opening of the resist pattern film viewed from above is linear, the line width of the resist pattern film is typically 0.1 to 50 μm, and preferably 0.3 to 10 μm. Within the above range, there is more apparent effect of the method for producing a resist pattern film of the present invention.

The standing wave trace of the resist pattern film can be confirmed by observing a cross section of the resist pattern film with an electron microscope. When the shape of the opening of the resist pattern film viewed from above is linear, the width (W4) of the standing wave trace is typically less than 40 nm, and preferably less than 20 nm.

### [Method for Producing Plated Formed Product]

The method for producing a plated formed product of the present invention includes a step (4) of performing a plating treatment by using, as a mold, the substrate having the resist pattern film produced by the method for producing the resist pattern film of the present invention.

### <Step (4)>

Examples of the plating treatment include a wet plating treatment such as an electrolytic plating treatment, an electroless plating treatment, and a molten plating treatment, and a dry plating treatment such as chemical vapor deposition and sputtering. In a case where a wiring or a connection terminal are formed in processing at the wafer level, the electrolytic plating treatment is typically performed.

Before the electrolytic plating treatment is performed, a pretreatment such as asking treatment, flux treatment, and desmear treatment can be performed in order to enhance affinity between the inner wall surface of the resist pattern and the plating solution.

In the case of the electrolytic plating treatment, a layer formed on the inner wall of the resist pattern by sputtering or electroless plating treatment can be used as the seed layer, and when a substrate having a metal film on the surface is used, the metal film can also be used as the seed layer. A barrier layer may be formed before the seed layer is formed, and the seed layer can be used as the barrier layer.

Examples of the plating solution used for the electrolytic plating treatment include: a copper plating solution containing copper sulfate, copper pyrophosphate, or the like; a gold plating solution containing gold potassium cyanide; and a nickel plating solution containing nickel sulfate or nickel carbonate.

The conditions for the electrolytic plating treatment can be appropriately selected depending on, for example, the type of the plating solution, and for example, in the case of the electrolytic plating treatment with copper sulfate, typically the temperature is 10 to 90° C. and the current density is 0.1 to 100 A/dm². Different plating treatments can be sequentially performed as the plating treatment. For example, a copper-pillar bump can be formed by first performing a copper plating treatment, then performing a nickel plating treatment, and then performing a melting solder plating treatment.

The thickness of the plated formed product varies depending on the application thereof, and for example, is typically 5 to 80 μm in the case of a bump, and is typically 0.1 to 10 μm in the case of a wiring.

### <Other Steps>

In the method for producing a plated formed product of the present invention, other steps include a step of removing a resist pattern film (hereinafter, also referred to as “step (5)”) after step (4). Step (5) is performed by, for example, a resist stripping solution containing tetramethylammonium hydroxide, dimethyl sulfoxide, water, and/or N,N-dimethylformamide.

The method for producing a plated formed product of the present invention can further include a step of removing, for example, by a wet etching method the metal film in the region other than the region with the plated formed product formed.

### EXAMPLES

Hereinafter, the present invention will be described in more detail based on examples, but the present invention is not limited to these examples.

### <<Weight Average Molecular Weight (Mw) of Polymer>>

The weight average molecular weight (Mw) of the polymer was measured by the gel permeation chromatography method under the following conditions.
GPC apparatus: product name “HLC-8220-GPC” manufactured by Tosoh Corporation
Column: connection of columns TSK-M and TSK2500 manufactured by Tosoh Corporation in series
Solvent: tetrahydrofuran
Temperature: 40° C.
Detection method: refractive index method
Standard substance: polystyrene

### <Production of Photosensitive Resin Composition>

### Example 1A

A photosensitive resin composition in Example 1A was produced by uniformly mixing 100 parts by mass of polymer (A-1) having a monomer-derived structural unit represented by the following formula (A-1) (Mw=11000), 1 part by mass of photoacid generator (B-1) represented by the following formula (B-1), 0.34 parts by mass of quencher (C-1) represented by the following formula (C-1), and 0.1 parts by mass of surfactant (E-1) (trade name: “NBX-15”, manufactured by Neos Corporation) in a mixed solvent having components shown in the following Table 1 and content ratios thereof so as to have a solid content of 15% by mass.

### Examples 2A to 5A and Comparative Examples 1A to 4A

Photosensitive resin compositions of Examples 2A to 5A and Comparative Examples 1A to 4A were produced in the same manner as in Example 1A except that the components shown in the following Table 1 and the contents thereof were used in Example 1A.

TABLE 1

| | | Photoacid | | | | | | Mixed solvent | | | | Solid |
|---|---|---|---|---|---|---|---|---|---|---|---|---|
| | Polymer | generator | Quencher | Quencher | Quencher | Quencher | Surfactant | Solvent | Solvent | Solvent | Solvent | content |
| | (A-1) | (B-1) | (C-1) | (C-2) | (C-3) | (C-4) | (E-1) | (D1-1) | (D2-1) | (D2-2) | (D3-1) | concentration |
| Example 1A | 100 parts | 1 part by | 0.34 parts | | | | 0.1 parts | 90% by | 10% by | | | 15% by |
| | by mass | mass | by mass | | | | by mass | mass | mass | | | mass |
| Example 2A | 100 parts | 1 part by | 0.34 parts | | | | 0.1 parts | 90% by | | 10% by | | 15% by |
| | by mass | mass | by mass | | | | by mass | mass | | mass | | mass |
| Example 3A | 100 parts | 1 part by | | | 0.34 parts | | 0.1 parts | 90% by | | 10% by | | 15% by |
| | by mass | mass | | | by mass | | by mass | mass | | mass | | mass |
| Example 4A | 100 parts | 1 part by | 0.34 parts | | | | 0.1 parts | 70% by | 30% by | | | 15% by |
| | by mass | mass | by mass | | | | by mass | mass | mass | | | mass |
| Example 5A | 100 parts | 1 part by | 0.34 parts | | | | 0.1 parts | 50% by | 50% by | | | 15% by |
| | by mass | mass | by mass | | | | by mass | mass | mass | | | mass |
| Comparative | 100 parts | 1 part by | 0.34 parts | | | | 0.1 parts | 100% | | | | 15% by |
| Example 1A | by mass | mass | by mass | | | | by mass | by | | | | mass |
| | | | | | | | | mass | | | | |
| Comparative | 100 parts | 1 part by | 0.34 parts | | | | 0.1 parts | 90% by | | | | 15% by |
| Example 2A | by mass | mass | by mass | | | | by mass | mass | | | 10% by | mass |
| Comparative | 100 parts | 1 part by | | 0.5 parts | | | 0.1 parts | 100% | | | mass | 15% by |
| Example 3A | by mass | mass | | by mass | | | by mass | by | | | | mass |
| | | | | | | | | mass | | | | |
| Comparative | 100 parts | 1 part by | | | | 0.34 parts | 0.1 parts | 90% by | | 10% by | | 15% by |
| Example 4A | by mass | mass | | | | by mass | by mass | mass | | mass | | mass |

The detail of each component shown in Table 1 is shown below.

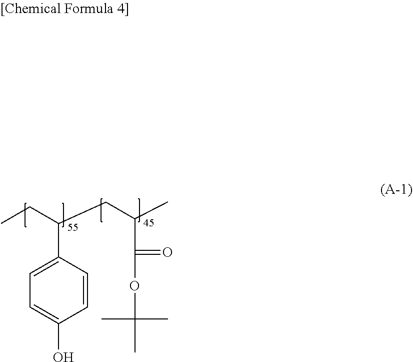

The suffix in parentheses in formula (A-1) indicates the content ratio (mol %) of each structural unit.

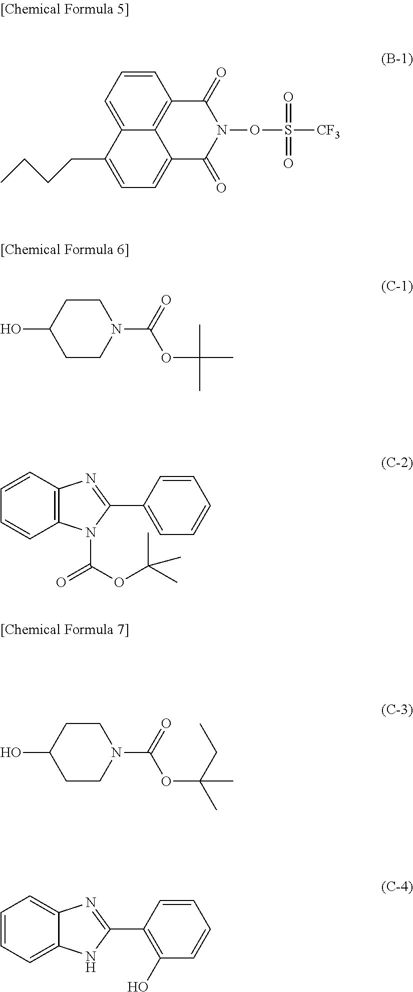

The distribution coefficients of quencher (C-1) and quencher (C-2) are 0.781 and 4.876, respectively.

The distribution coefficients of quencher (C-3) and quencher (C-4) are 1.310 and 2.887, respectively.
Solvent (D1-1): propylene glycol monomethyl ether acetate (distribution coefficient=0.5992, standard boiling point=146° C.)
Solvent (D2-1): 3-methoxybutyl acetate (distribution coefficient=0.9320, standard boiling point=172° C.)
Solvent (D2-2): dipropylene glycol methyl ether acetate (distribution coefficient=0.7326, standard boiling point=209° C.)
Solvent (D3-1): γ-butyrolactone (distribution coefficient=−0.803, standard boiling point=204° C.)

The distribution coefficient is a value obtained from Chem Draw Professional 17.1 manufactured by PerkinElmer Co., Ltd.

### <Production of Resist Pattern Film>

### Example 1B

The photosensitive resin composition of Example 1A was spin-coated on a copper sputtered film of a silicon wafer substrate provided with the copper sputtered film by a coater/developer (product name “MARK-8”) manufactured by Tokyo Electron Limited, and then heated at 110° C. for 60 seconds to be formed into a resin film. The resin film was exposed by using a stepper (model “NSR-i10D”, manufactured by Nikon Corporation) through a pattern mask. The exposed coating was heated at 90° C. for 60 seconds and then immersed in a 2.38% by mass of tetramethylammonium hydroxide aqueous solution for 90 seconds to perform development. Thereafter, washing was performed with flowing water, nitrogen was blown, and the resist pattern film of Example 1B (resist pattern film serving as one line/one space, a thickness of the resist pattern film=1.5 μm) was formed on the copper sputtered film of the substrate.

The shape of the cross section of the resist pattern film of Example 1B was observed with an electron microscope. The shape and standing wave trace of the resist pattern film were evaluated by the following method and criteria. The measurement and evaluation results are shown in Table 2.

### <<Shape of Resist Pattern Film>>

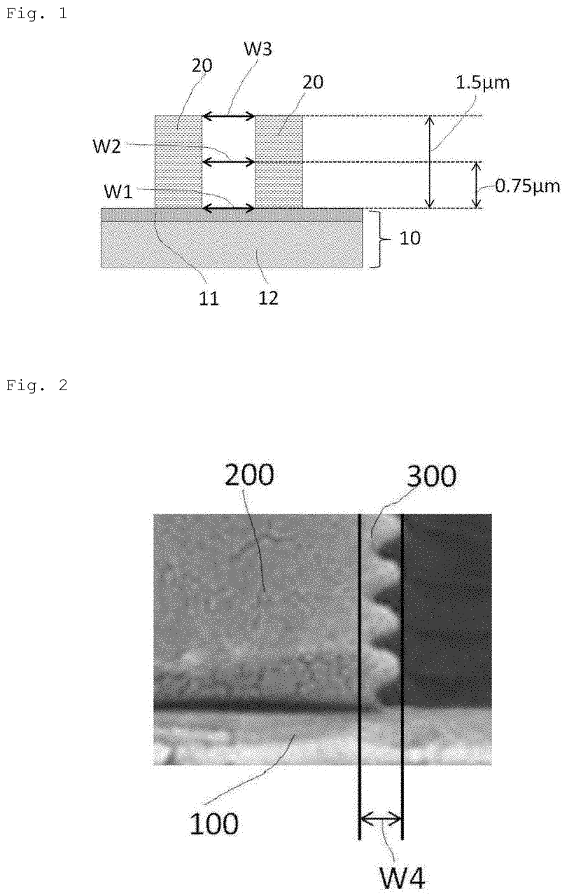

As shown in FIG. 1, widths (W1 to W3) of spaces formed by the resist pattern film at heights of 0 μm, 0.75 μm, and 1.5 μm from the substrate were measured. In addition, W2/W1 and W3/W1 were calculated, and the rectangularity of the pattern was evaluated according to the following criteria.

### (Evaluation Criteria for Rectangularity)

AA: 0.95 or more and 1.05 or less

BB: more than 1.05 and 1.15 or less

CC: more than 1.15

### <<Standing Wave Trace>>

As shown in FIG. 2, a width (W4) of the standing wave trace was measured.

### Examples 2B to 5B and Comparative Examples 1B to 4B

Resist pattern films of Examples 2B to 5B and Comparative Examples 1B to 4B were formed in the same manner as in Example 1B and evaluated except that the photosensitive resin composition shown in Table 2 was used in Example 1B instead of the photosensitive resin composition of Example 1A. The evaluation results are shown in Table 2.

TABLE 2

| | Photosensitive | | | | | Standing |
|---|---|---|---|---|---|---|
| | resin | Shape of resist pattern film | | | | wave trace |
| | composition | W1 | W2 | W3 | Rectangularity | W4 |
| Example 1B | Example 1A | 0.971 μm | 0.943 μm | 0.943 μm | AA | 29 nm |
| Example 2B | Example 2A | 1.000 μm | 0.971 μm | 0.971 μm | AA | 23 nm |
| Example 3B | Example 3A | 0.988 μm | 0.972 μm | 0.973 μm | AA | 25 nm |
| Example 4B | Example 4A | 0.976 μm | 0.991 μm | 0.989 μm | AA | 21 nm |
| Example 5B | Example 5A | 0.854 μm | 0.956 μm | 0.954 μm | BB | 23 nm |
| Comparative | Comparative | 1.000 μm | 0.971 μm | 0.943 μm | AA | 71 nm |
| Example 1B | Example 1A | | | | | |
| Comparative | Comparative | 0.800 μm | 0.943 μm | 0.914 μm | CC | 37 nm |
| Example 2B | Example 2A | | | | | |
| Comparative | Comparative | 0.914 μm | 1.057 μm | 1.057 μm | CC | 57 nm |
| Example 3B | Example 3A | | | | | |
| Comparative | Comparative | 0.987 μm | 1.002 μm | 1.011 μm | AA | 42 nm |
| Example 4B | Example 4A | | | | | |

### REFERENCE SIGNS LIST

10, 100 Substrate
11 Copper sputtered film
12 Silicon wafer
20, 200 Resist pattern film
300 Standing wave trace

1. A photosensitive resin composition comprising:
a polymer (A) having an acid dissociative group; a photoacid generator (B); a carbamic acid ester (C) having a hydroxyl group; and a solvent (D),
the solvent (D) comprising:
at least one solvent (D1) selected from the group consisting of propylene glycol monomethyl ether acetate, propylene glycol monomethyl ether, ethyl lactate, methyl 3-methoxypropionate, and cyclohexanone; and
at least one solvent (D2) selected from the group consisting of dipropylene glycol dimethyl ether, dipropylene glycol methyl ethyl ether, dipropylene glycol diethyl ether, dipropylene glycol methyl ether acetate, dipropylene glycol ethyl ether acetate, 3-methoxybutyl acetate, 1,4-butanediol diacetate, and 1,3-butylene glycol diacetate.

2. The photosensitive resin composition according to claim 1, wherein a content ratio of the solvent (D1) in 100% by mass of the solvent (D) is 70 to 99% by mass, and a content ratio of the solvent (D2) is 1 to 30% by mass.

3. The photosensitive resin composition according to claim 1, wherein the solvent (D1) is propylene glycol monomethyl ether acetate.

4. The photosensitive resin composition according to claim 1, wherein the carbamic acid ester (C) having a hydroxyl group is a carbamic acid ester having an acid dissociative group.

5. The photosensitive resin composition according to claim 1, wherein a content of the carbamic acid ester (C) having a hydroxyl group in the photosensitive resin composition is 0.1 to 1 parts by mass with respect to 100 parts by mass of the solvent (D2).

6. A method for producing a resist pattern film, the method comprising:
forming a resin film of the photosensitive resin composition according to claim 1 on a metal film of a substrate, the substrate having the metal film on a surface thereof;
exposing at least a part of the resin film; and
developing the exposed resin film.

7. A method for producing a plated formed product, the method comprising performing a plating treatment with a substrate, as a mold, having a resist pattern film formed by the method for producing the resist pattern film according to claim 6.

8. The photosensitive resin composition according to claim 2, wherein the solvent (D1) is propylene glycol monomethyl ether acetate.

9. The photosensitive resin composition according to claim 2, wherein the carbamic acid ester (C) having a hydroxyl group is a carbamic acid ester having an acid dissociative group.

10. The photosensitive resin composition according to claim 3, wherein the carbamic acid ester (C) having a hydroxyl group is a carbamic acid ester having an acid dissociative group.

11. The photosensitive resin composition according to claim 8, wherein the carbamic acid ester (C) having a hydroxyl group is a carbamic acid ester having an acid dissociative group.

12. The method according to claim 6, wherein a content ratio of the solvent (D1) in 100% by mass of the solvent (D) is 70 to 99% by mass, and a content ratio of the solvent (D2) is 1 to 30% by mass.

13. The method according to claim 6, wherein the solvent (D1) is propylene glycol monomethyl ether acetate.

14. The method according to claim 6, wherein the carbamic acid ester (C) having a hydroxyl group is a carbamic acid ester having an acid dissociative group.

15. The method according to claim 6, wherein a content of the carbamic acid ester (C) having a hydroxyl group in the photosensitive resin composition is 0.1 to 1 parts by mass with respect to 100 parts by mass of the solvent (D2).

16. The method according to claim 7, wherein a content ratio of the solvent (D1) in 100% by mass of the solvent (D) is 70 to 99% by mass, and a content ratio of the solvent (D2) is 1 to 30% by mass.

17. The method according to claim 7, wherein the solvent (D1) is propylene glycol monomethyl ether acetate.

18. The method according to claim 7, wherein the carbamic acid ester (C) having a hydroxyl group is a carbamic acid ester having an acid dissociative group.

19. The method according to claim 7, wherein a content of the carbamic acid ester (C) having a hydroxyl group in the photosensitive resin composition is 0.1 to 1 parts by mass with respect to 100 parts by mass of the solvent (D2).
